(19) United States
(12) Patent Application Publication
(10) Pub. No.: US 2021/0397081 A1
(43) Pub. Date: Dec. 23, 2021

(54) METHOD FOR MANUFACTURING GRATING REFERENCE MATERIALS HAVING A SELF-TRACEABILITY

(71) Applicants: Tongji University, Shanghai (CN); Shanghai Institute of Applied Physics, Chinese Academy of Sciences, Shanghai (CN)

(72) Inventors: Xinbin CHENG, Shanghai (CN); Xiao DENG, Shanghai (CN); Jun ZHAO, Shanghai (CN); Shumin YANG, Shanghai (CN); Chaofan XUE, Shanghai (CN); Yanqing WU, Shanghai (CN); Renzhong TAI, Shanghai (CN); Jie LIU, Shanghai (CN); Zhenjie GU, Shanghai (CN); Tongbao LI, Shanghai (CN)

(21) Appl. No.: 17/303,328

(22) Filed: May 26, 2021

(30) Foreign Application Priority Data
Jun. 22, 2020 (CN) 202010575583.6
Jun. 22, 2020 (CN) 202010575620.3

(51) Int. Cl. G03F 1/76; G03F 7/20

(52) U.S. Cl. CPC G03F 1/76; G03F 7/2004; G03F 7/70408

(57) ABSTRACT

A method for manufacturing grating reference materials having a self-traceability includes: acquiring a mask substrate including a window region and a non-window region; fabricating, a self-traceability mask on the mask substrate by using a laser-focused atomic deposition technique; acquiring a photoresist sample including an extreme ultraviolet photoresist and a second substrate; exposing the extreme ultraviolet photoresist by combining the self-traceability mask with the soft x-ray interference lithography, and then performing a development process after exposing to obtain a photoresist grating structure; and transferring the photoresist grating structure to the second substrate to obtain the grating reference materials.

### CROSS-REFERENCE TO RELATED APPLICATION

This application claims priority to Chinese Patent Application No. 202010575620.3 filed Jun. 22, 2020, and Chinese Patent Application No. 202010575583.6 filed Jun. 22, 2020, the disclosures of which are incorporated herein by reference in their entireties.

### TECHNICAL FIELD

The present application relates to the field of nanograting reference materials, for example, relates to a method for manufacturing grating reference materials having a self-traceability.

### BACKGROUND

Along with advances of nanotechnology, the characteristic dimensions of devices are up to the order of nanometers. Consequently, uncertainties and errors increase significantly in a manufacturing process, which causes more and more bad influences on the performance of the devices. Nano-metrology is for measuring and representing nano-scale devices, plays an important role in process control and quality management for manufacturing the nano-scale devices, and is a key science and technology problem in related fields such as a micro-electro-mechanical system (MEMS), ultra-precision machining and nanomedicine, nanobiology. The nano-metrology is a precondition for achieving the accuracy and reliability of values for nano-scale measurement quantity, but the difficulty lies in nano-scale precision and traceability. The measurement results obtained by traditional commercial measurement instruments, such as a scanning electron microscope (SEM) or an atomic force microscope (AFM), have nano-scale measurement errors due to limitations from their operating principles and some inherent properties. For example, when a same sample is measured by different instruments, the measurement results of the sample may be completely different. A way to solve this problem is to use a nano-metrology transfer standard. The nano-metrology transfer standard may be reference materials having determined geometric dimensions and manufactured by a specific nanofabrication technology. After the instruments, such as the SEM or the AFM, are calibrated by the nano-metrology transfer standard, the measurement results may be traceable to the national standard or the definition of the International System of Units (SI) (meter), and the accuracy and reliability of the measurement are greatly improved.

Nanograting reference materials are common nano-metrology transfer standard. The manufacturing process is mainly divided into two types according to the traceability of the nanograting reference materials. The first type cannot be directly traceable to natural fundamental constants or the definition of SI (meter). For example, the nanograting reference materials, which are manufactured by traditional lithography, an electron beam etching technology or a multilayer film technology, etc., have no traceability, so the nanograting reference materials need to be measured by the National Measure Institute to definite values, and then the characteristic dimensions of the nanograting reference materials can be traceable to the measuring instruments of the National Measure Institute and can be used for calibrating commercial instruments accordingly. The second type can be directly traceable to the natural fundamental constants or the definition of SI (meter), for example, line width reference materials based on silicon lattice investigated by NIST and nanograting reference materials having self-traceability and manufactured using laser-focused atomic deposition technique by Tongji University and National Institute of Metrology, China.

The first type of the grating reference materials does not have the traceability and cannot have the characteristics of both large area and small pitch value.

The second type of the grating reference materials have the traceability, but the pitch value of the grating reference materials is single and cannot be flexibly adjusted according to actual demands.

As science and technology develops, the research of nanotechnology has entered into a dimension of 10-nanometer. A series of reference materials having the high-precision and traceability are urgently needed to calibrate the instruments for measuring the devices at a scale of 100 nanometers and even tens of nanometers. Therefore, new requirements have been proposed on the method for manufacturing the reference materials.

### SUMMARY

The following is a summary of the subject matter described herein in detail, which is not intended to limit the scope of the claims.

A method for manufacturing grating reference materials having a self-traceability is provided in the embodiments of the present application. The method is based on laser-focused atomic deposition technique and soft x-ray interference lithography. The method includes the following steps: acquiring a mask substrate, where the mask substrate includes a window region and a non-window region, the window region includes a first substrate, and the non-window region includes a film and the first substrate; fabricating a self-traceability mask on the mask substrate by using the laser-focused atomic deposition technique; acquiring a photoresist sample which includes an extreme ultraviolet photoresist and a second substrate; exposing the extreme ultraviolet photoresist by combining the self-traceability mask with the soft x-ray interference lithography, and then performing a development process after exposing to obtain a photoresist grating structure; and transferring the photoresist grating structure to the second substrate to obtain the grating reference materials. The grating reference materials have characteristics of the self-traceability and small pitch value; where a theoretical pitch value of a mask grating structure of the self-traceability mask is 2N times a theoretical pitch value of the grating reference materials, and N is a positive integer greater than or equal to 1.

Other aspects can be understood after reading the drawings and the detailed description in embodiments.

### BRIEF DESCRIPTION OF DRAWINGS

FIG. 1 shows a flowchart illustrating a method for manufacturing grating reference materials having a self-traceability according to embodiments of the present application.

FIG. 2 shows a side view of a mask substrate according to embodiments of the present application.

FIG. 3 shows a front view of a mask substrate according to embodiments of the present application.

FIG. 4 shows a schematic diagram of laser-focused atomic deposition technique according to embodiments of the present application.

FIG. 5 shows a schematic diagram of soft x-ray interference lithography according to embodiments of the present application.

FIG. 6 shows a schematic diagram of grating structure pattern transfer by reactive ion beam etching according to embodiments of the present application.

FIG. 7 shows a schematic structure diagram of a synchrotron radiation x-ray interference lithography apparatus according to embodiments of the present application.

FIG. 8 shows a flowchart of an extreme ultraviolet photoresist quality detection method based on a self-traceability grating according to embodiments of that present application.

FIG. 9 shows a principle diagram of a mask grating manufactured by using atomic lithography according to embodiments of the present application.

FIG. 10 shows a schematic diagram of a one-dimensional EUV photoresist line pattern obtained based on double grating interference lithography according to embodiments of the present application.

FIG. 11 shows an image of an exposure EUV photoresist sample produced by a scanning electron microscope according to embodiments of the present application.

FIG. 12 shows a schematic diagram of line edge roughness and line width roughness measured by using a pitch value of a self-traceability grating as a scale according to embodiments of the present application.

FIG. 13 shows a schematic diagram of a boundary position deviation value and a line width deviation value according to embodiments of the present application.

FIG. 14 shows a schematic diagram of key dimensions of an exposure sample according to embodiments of the present application.

### INDEX LIST

1 film
2 first substrate
3 non-window region
4 window region
5 atomic beam
6 laser
7 laser standing wave field
8 grating structure
9 x-ray light
10 diffraction light
11 photoresist
12 second substrate
13 photoresist grating structure
14 reactive ion beam etching process
15 grating reference material
101 extreme ultraviolet light source
102 incident slit member
103 first cylindrical lens
104 second cylindrical lens
105 exit slit member
106 shutter
107 photodiode
108 mask grating
109 XIL vacuum chamber
110 charge-coupled device
201 chromium atom furnace
202 cooling laser beam
203 standing wave field
204 optical potential well
205 grating structure
206 substrate
301 extreme ultraviolet light beam
302 pattern of a photoresist to be detected
401 pitch value of a pattern of a photoresist to be detected
402 line edge deviation value at some point
403 line edge line width value at some point
404 ideal line edge
501 top dimension
502 middle dimension
503 bottom dimension

### DETAILED DESCRIPTION

The present application is described below in detail in conjunction with drawings and embodiments. The embodiments are implemented on the basis of the solution of the present application. Detailed embodiments and specific operation processes are given, but the scope of the present application is not limited to the embodiments described below.

As illustrated in the above, in the first type, a method for manufacturing nanograting reference materials that cannot be directly traceable to the natural fundamental constants or the SI unit definition of meter includes traditional lithography, an electron beam etching, a multilayer film technology and the like. For the traditional lithography, although a large-area grating reference materials can be manufactured by using the traditional lithography, the minimum pitch value of the grating reference materials can only be on the order of 200 nm due to the constraint of visible light wavelength used in the traditional lithography. For the electron beam etching, although the pitch of grating reference materials may be at the scale of 10 to 100 nm, grating reference materials having a small pitch and a large area can only be manufactured by multi-field splicing due to the constraint of a single-field exposure area of etching equipment, and such grating reference materials are difficult to satisfy the requirements of homogeneity and traceability. For the multilayer film technology, although a reference material on the scale of tens of nanometers can be manufactured, due to the constraint of coating conditions in the manufacturing process, the film thickness of the reference material will drift with an increase in the number of coating layers, resulting in a smaller area of the grating structure region of the reference material. In addition, for the traditional lithography, although the pitch value of a reference material may be at the scale of 100 nm or at the scale of tens of nanometers, no traceability is provided in the manufacturing process. To ensure that a measurement value of the reference material can be traceable to the SI unit definition of meter, calibration by a measuring instrument of the National Measure Institute is needed, resulting in a long traceability chain and large uncertainty. For example, for the grating material having a pitch value of 100 nm (nominal pitch value of 100 nm±2 nm) of the VLSI Standards, Inc., the uncertainty is 1 nm.

In a second-type method for manufacturing grating reference materials that can be directly traceable to the natural fundamental constants or the SI unit definition of meter, the laser-focused atomic deposition technique is used by Tongji University and National Institute of Metrology, China. For the grating reference materials manufactured by using the laser-focused atomic deposition technique (also referred to as atomic lithography), an atomic deposition position in the manufacturing process strictly corresponds to the node (antinode) position of the laser standing wave field, and laser wavelength is locked on a known atomic transition energy level through a laser-induced fluorescence frequency stabilization technology so that the pitch of the grating reference materials can be strictly traceable to the natural transition frequency between atomic transition energy levels. It is a better solution for manufacturing grating reference materials having high accuracy, high precision. The area of the grating region reaches the order of millimeters and has good intra-sample consistency. However, the grating reference materials manufactured by using the laser-focused atomic deposition technique have a single pitch value, and the pitch value of the grating reference materials cannot be flexibly adjusted according to actual demands.

As science and technology develops, the research of nanotechnology in dimensionality has come to the 10-nanometer level. A series of high-precision grating materials with traceable measurement quantity are urgently needed to calibrate measurements at the scale of 100 nm and at the scale of tens of nanometers. Therefore, new requirements have been imposed on the method for manufacturing a grating material.

As a consequence, a method for manufacturing grating reference materials having a self-traceability based on the laser-focused atomic deposition technique and soft x-ray interference lithography is provided in the embodiments of the present application.

### Embodiment 1

This embodiment provides a method for manufacturing grating reference materials having a self-traceability. The method is based on laser-focused atomic deposition technique and soft x-ray interference lithography and includes content described below.

A mask substrate is acquired, where the mask substrate includes a window region and a non-window region, the window region includes a first substrate, and the non-window region includes a film and the first substrate.

A self-traceability mask is fabricated on the mask substrate by using the laser-focused atomic deposition technique.

A photoresist sample is acquired, where the photoresist sample includes an extreme ultraviolet photoresist and a second substrate; the extreme ultraviolet photoresist is exposed by combining the soft x-ray interference lithography with the self-traceability mask fabricated in the above step, and then a development process is performed after exposing to obtain a photoresist grating structure.

Optionally, the extreme ultraviolet photoresist is exposed through the double grating interference to form an extreme ultraviolet photoresist pattern, and then a photoresist grating structure is obtained by using the extreme ultraviolet photoresist pattern through a development process.

The photoresist grating structure is transferred to the second substrate to obtain the grating reference materials. The grating reference materials have the self-traceability and a relatively small pitch value.

A theoretical pitch value of a mask grating structure of the self-traceability mask is 2N times a theoretical pitch value of the grating reference material, and N is a positive integer greater than or equal to 1.

Optionally, N is the diffraction order of grating in the double grating interference, and the N can be a first order or a second order; in the case where N is the first order, N=1; and in the case where N is the second order, N=2.

Optionally, the theoretical pitch value of the grating reference materials are calculated by a following expression:

$$P = \frac{{P}_{0}}{2 N} .$$

P denotes the theoretical pitch value of the grating reference material, and P₀ denotes the pitch value of the mask grating structure of the self-traceability mask.

Optionally, a theoretical pitch value of the photoresist grating structure is the same as the theoretical pitch value of the grating reference materials. That is to say, the photoresist grating structure, the extreme ultraviolet photoresist pattern and the grating reference materials all have the same theoretical pitch value.

Optionally, the window region is x-ray transparent, the non-window region is x-ray opaque, the number of window regions is two, and the two window regions have a same size and are symmetrically distributed.

Optionally, a soft x-ray used in the soft x-ray interference lithography has coherence.

In the case where N is the first order, the two window regions satisfy:

D≥0.2L, and D+2L≤L_{C}.

In the case where N is the second order, the two window regions satisfy:

D≥3L, and D+2L≤L_{C}, L≤300 μm.

D denotes a width of a non-window region between the two window regions, L denotes a width of each of the two window regions, and L_{C} denotes a coherence length of the soft x-ray passing through the self-traceability mask.

Optionally, in the case where N is the first order, a peak-valley height value H of the photoresist grating structure and a full width at half maximum (FWHM) of the photoresist grating structure respectively satisfy:

$$5 \% \leq \frac{H}{{P}_{0}} \leq 50 \% and$$

$$15 \% \leq \frac{F W H M}{{P}_{0}} \leq 85 \% .$$

In the case where N is the second order, a peak-valley height value H of the photoresist grating structure and an FWHM of the photoresist grating structure respectively satisfy:

$$5 \% \leq \frac{H}{{P}_{0}} \leq 70 \% and$$

$$20 \% \leq \frac{F W H M}{{P}_{0}} \leq 80 \% .$$

P₀ denotes the theoretical pitch value of the mask grating structure of the self-traceability mask.

Optionally, a thickness h of the film of the mask substrate satisfies: 50 nm≤h≤300 nm, a surface roughness of the film is less than 0.3 nm, and a maximum height value of a surface profile of the film is less than 2 nm.

Optionally, an atom used in the laser-focused atomic deposition technique is a chromium atom, an aluminum atom or an iron atom.

Optionally, a divergence angle of an extreme ultraviolet light source used in the soft x-ray interference lithography is less than 1 mrad, and the theoretical pitch value of the mask grating structure of the self-traceability mask is greater than three times a wavelength of the extreme ultraviolet light source.

Optionally, transferring the photoresist grating structure to the second substrate includes: using a reactive ion beam etching process to transfer the photoresist grating structure to the second substrate.

Optionally, the extreme ultraviolet photoresist is made of poly-methyl methacrylate (PMMA), hydrogen silisesquipoxane (HSQ) or ZEP, and the second substrate is made of silicon, silicon nitride, aluminum or chromium.

Optionally, a theoretical pitch value of the extreme ultraviolet photoresist pattern has characteristics of the self-traceability and is configured as an accurate scale to determine a quality of the extreme ultraviolet photoresist.

Compared with the related art, this embodiment of the present application has advantages described below.

(1) In this embodiment of the present application, the grating having a self-traceability and fabricated by using the laser-focused atomic deposition technique is used as the mask. After light exposure and developing processes on the photoresist by using soft x-rays, the photoresist grating structure is transferred to the substrate by using the reactive ion beam etching to obtain the grating reference material. The grating reference materials have the characteristics of self-traceability, small pitch, large-area homogeneity, long-term stable storage and use, and the like.

In the related art, the grating reference materials manufactured by using the laser-focused atomic deposition technique can be traceable to the atomic transition energy level in the manufacturing process and accordingly has a self-traceability. Meanwhile, the grating pitch of the grating reference materials is in high precision, and the uncertainty is less than 0.1 nm. However, the pitch value of the grating reference materials is relatively large due to the limitation of laser wavelength and an atomic type.

On such basis, in the process of manufacturing the grating reference material, not only the laser-focused atomic deposition technique but also the soft x-ray interference lithography is used in this embodiment of the present application. A combination of the two technologies can accurately reduce the pitch value of the grating reference material, thus solving the problem of the relatively large pitch value of the grating reference materials manufactured directly by using the laser-focused atomic deposition technique.

The solution provided by this embodiment of the present application overcomes the problem that the pitch value of the self-traceability grating is single and inherits the advantages of high precision, traceability, accurate reduction of a pitch value and the like. A solution is provided for manufacturing a reference material having a small pitch, traceability at the scale of 100 nm and less, and high precision.

In the aspect of magnitude of the pitch value of a reference material, on the basis of the laser-focused atomic deposition technique, the manufacturing method provided in this embodiment of the present application can provide reference materials having a series of pitches at the scale of 100 nm and less, and the pitch value of the manufactured reference material is accurately equal to ½N of the pitch value of the self-traceability grating reference materials manufactured by using the laser-focused atomic deposition technique, thus expanding the application of the self-traceability grating reference material.

In the aspect of traceability of a reference material, the reference material manufactured by the solution provided in this embodiment of the present application has traceability compared with the reference material manufactured by using the traditional lithography, such as the electron beam etching or the multilayer film technology. To ensure the traceability of the measurement value of the grating, the pitch value of the self-traceability grating reference materials provided in this embodiment is traceable to the self-traceability mask grating.

In the aspect of precision of a reference material, the reference material manufactured by the solution provided in this embodiment of the present application has a pitch value in high precision, has a uncertainty better than 0.5 nm, and satisfies a demand for high-precision reference material compared with the reference material manufactured by using the traditional lithography, such as the electron beam etching or the multilayer film technology.

In the aspect of structure homogeneity of a reference material, the reference material manufactured by the solution provided in this embodiment of the present application has excellent homogeneity and has an area dimension up to the order of hundreds of microns compared with the reference material manufactured by using the electron beam etching or the multilayer film technology.

(2) In the mask substrate machining step of this embodiment of the present application, the mask substrate is divided into a window region and a non-window region, the window region only includes a first substrate, and a silicon substrate having a thickness of 290 μm is usually selected as the first substrate. When interference is performed by using the mask substrate, the background light in the interference lithography region and through the window region is extremely weak, improving the contrast of interference fringes and conducive to the performing of interference lithography experiments.

(3) The mask manufactured in this embodiment of the present application can satisfy the optical properties for x-rays. The main parameter of the mask is the grating diffraction efficiency for x-rays. The grating diffraction efficiency is closely related to a grating material and grating structural features (height, width and bottom layer). In addition, the bottom layer of a metal grating strongly absorbs x-rays, so it is also necessary to consider reducing the absorption of x-rays by the bottom layer of the metal grating. On such basis, this embodiment of the present application limits conditions for selecting the peak-valley height value and the full width at half maximum of the photoresist grating structure, so as to effectively reduce the absorption of x-rays by the bottom layer of the metal grating of the mask.

(4) This embodiment of the present application limits conditions for selecting geometric dimensions of a mask substrate in the soft x-ray interference lithography, and also considers the influence of coherence of a soft x-ray light, so as to ensure the quality of the exposure grating structure and balance the interference of a high-order diffraction light on an exposure region.

### Embodiment 2

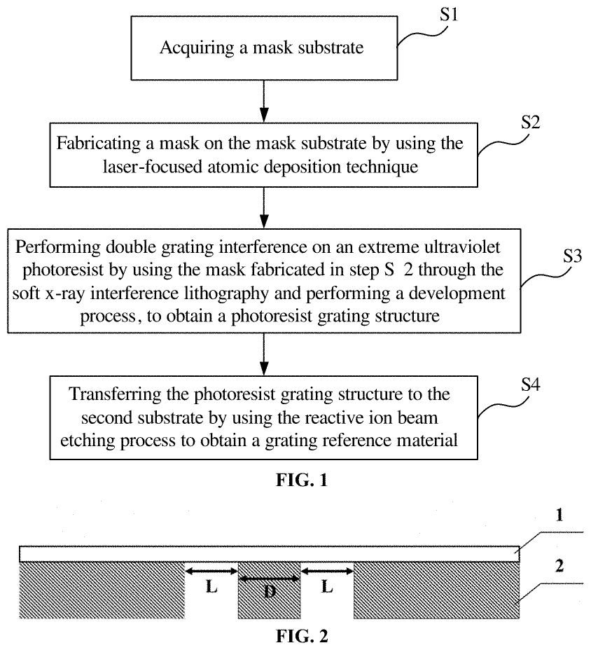

As shown in FIG. 1, this embodiment provides a method for manufacturing self-traceability grating reference materials whose pitch value is accurately reduced. The method includes steps described below.

In mask substrate acquisition step S1, a mask substrate is acquired. The mask substrate is divided into a window region and a non-window region, the window region includes a first substrate, and the non-window region includes a film and the first substrate.

The window region is x-ray transparent, the non-window region is x-ray opaque, and the number of window regions is two. The two window regions have a same size, are symmetrically distributed, and are located in the central region of the mask substrate.

A thickness h of the film of the mask substrate satisfies: 50 nm≤h≤300 nm, a surface roughness of the film is less than 0.3 nm, and a maximum height value of a surface profile of the film is less than 2 nm.

In mask manufacturing step S2, a mask is fabricated on the mask substrate by using the laser-focused atomic deposition technique. The mask has a self-traceability characteristic.

An atom used in the laser-focused atomic deposition technique is a chromium atom, an aluminum atom or an iron atom.

The laser-focused atomic deposition technique is introduced in the invention patent entitled “method of fabricating laser controlled nanolithography”, and the number of announcement of grant of patent right is U.S. Pat. No. 5,360,764. In such patent, the Applicant provides a method of fabricating a laser controlled nanostructure. In such method, atoms may be deposited on a substrate in which a beam of atoms is optically focused utilizing a laser beam. Specifically, the laser beam is used to form a standing wave above the surface of a substrate. As the beam of atoms passes through the standing wave, the atoms are focused by dipole force interactions. The deposition of atoms is focused into parallel lines. Thus, it can be known that atoms in an atomic beam can be focused by using the standing waves.

In photoresist grating structure manufacturing step S3, a photoresist sample is acquired, where the photoresist sample includes an extreme ultraviolet photoresist and a second substrate; the extreme ultraviolet photoresist is exposed by using the mask through the soft x-ray interference lithography, and then a photoresist grating structure is obtained through a development process.

The used diffraction order of grating in the soft x-ray interference lithography is a first order or a second order.

In grating reference material acquisition step S4, the photoresist grating structure is transferred to the second substrate by using the reactive ion beam etching process to obtain a grating reference material.

The grating reference materials have the self-traceability characteristic and a relatively small pitch value.

The expression of the pitch value of the grating reference materials is:

$$P = \frac{{P}_{0}}{2 N} .$$

P denotes the theoretical pitch value of the grating reference material, P₀ denotes the pitch value of the mask grating structure of the mask, and Nis an diffraction order of grating.

Some conditions of the manufacturing method in this embodiment are described below.

A soft x-ray used in the soft x-ray interference lithography has coherence. In the case where the diffraction order of grating is the first order, the two window regions satisfy:

D≥0.2L, and D+2L≤L_{C}

In the case where the diffraction order of grating is the second order, the two window regions satisfy:

D≥3L, and D+2L≤L_{C}, L≤300 μm

D denotes the width of a region (i.e., non-window region) between the two window regions, L denotes the width of each window region, and L_{C} denotes the coherence length of the soft x-ray passing through the mask. In the case where N is the first order, a peak-valley height value H of the photoresist grating structure and a full width at half maximum (FWHM) of the photoresist grating structure respectively satisfy:

$$5 \% \leq \frac{H}{{P}_{0}} \leq 50 \% \\ 15 \% \leq \frac{F W H M}{{P}_{0}} \leq 85 \%$$

In the case where N is the second order, a peak-valley height value H of the photoresist grating structure and a full width at half maximum (FWHM) of the photoresist grating structure respectively satisfy:

$$5 \% \leq \frac{H}{{P}_{0}} \leq 70 \% and$$

$$20 \% \leq \frac{FWHM}{{P}_{0}} \leq 80 \% .$$

P₀ denotes the pitch value of the mask grating structure of the mask.

A divergence angle of an extreme ultraviolet light source used in the soft x-ray interference lithography is less than 1 mrad. The mask is formed with the mask grating structure, and the pitch value of the mask grating structure is greater than three times the wavelength of the extreme ultraviolet light source.

The extreme ultraviolet photoresist is made of materials including PMMA, HSQ or ZEP, and the mask substrate is made of materials including silicon, silicon nitride, aluminum or chromium.

### Specific Implementation

After the method for manufacturing self-traceability grating reference materials whose pitch value is accurately reduced provided in this embodiment is implemented, traceable reference materials at the scale of 100 nanometers or less can be manufactured. The pitch value of the reference material is accurately equal to ½N of the pitch value of the self-traceability grating reference material, and N is a diffraction order. Meanwhile, the reference material has the characteristics of high precision and small uncertainty. The method achieves the manufacturing of the reference material by using implementation steps described below.

In the first step, a suitable mask substrate is designed and machined.

As shown in FIG. 2, the mask substrate is formed by a film 1 and a first substrate 2, the first substrate 2 is located below the film, and the first substrate 2 serves to support the film 1 so that the film 1 is not easily broken. The dimensions in FIG. 2 do not represent the true dimensions.

The film 1 is made of silicon nitride, silicon and other materials and has a thickness in the range of 50 nm to 300 nm. Generally, a film made of silicon nitride and having a thickness of 100 nm is selected and silicon nitride may be amorphous. The film 1 needs to be low in stress and not too thin in thickness because long-term exposure to a high-throughput synchrotron radiation light source will cause local temperature imbalance and high stress and too thin thickness will easily cause the film to break.

The first substrate 2 is made of silicon nitride, silicon and other materials, and the selection of this material is to give consideration to the selection of an etching rate ratio combined with the film material. The thickness of the first substrate 2 is in the range of 100 μm to 500 μm. Generally, a substrate made of silicon and having a thickness of 290 μm is selected, and silicon may be amorphous silicon or monocrystalline silicon. The parameter of the silicon substrate is selected according to the convenience of window-opening processing. Window-opening processing is to completely etch partial region of the silicon substrate material to the silicon nitride film by means of chemical etching on the side of silicon substrate, so that only the silicon nitride film is left in the partial region of the mask substrate. The region where only the silicon nitride film is left is referred to as a window region 4 (also referred to as an interference lithography region), and the region having both the silicon nitride film and the silicon substrate becomes a non-window region 3. X-ray light can pass through the window region 4, while x-ray light is completed blocked by the silicon substrate and thus cannot pass the non-window region 3 (also known as a light blocking region).

As shown in FIG. 3, in the design scheme of the mask substrate, the background light in the interference lithography region is extremely weak, improving the contrast of interference fringes and conducive to the performing of interference lithography experiments.

It is to be noted that in the window-opening process, the chemical etching scheme used is not unique, as long as requirements for geometric dimensions of the structures of the two window regions subjected to etching can be satisfied. Optionally, as shown in FIG. 3, the geometric dimensions refer to the width L of each window region and the width D of the opaque portion between the two window regions. The widths L and D determine the size of the exposure region and the exposure quality. On the other hand, how to choose a chemical etching scheme also depends on the interference lithography scheme. The surface morphology of the silicon nitride film is another important parameter in this step, and includes the surface roughness and the maximum height of a profile. The surface roughness must be less than 0.3 nm and the maximum height of the profile must not exceed 2 nm. The reason is that the surface morphology of silicon nitride will affect the quality of the self-traceability grating reference materials in the second step described below. Higher maximum height of the profile and higher surface roughness will lead to deterioration of the quality of the mask grating and deterioration of optical characteristics of the mask grating for x-rays.

In the second step, self-traceability grating reference materials are manufactured to a mask.

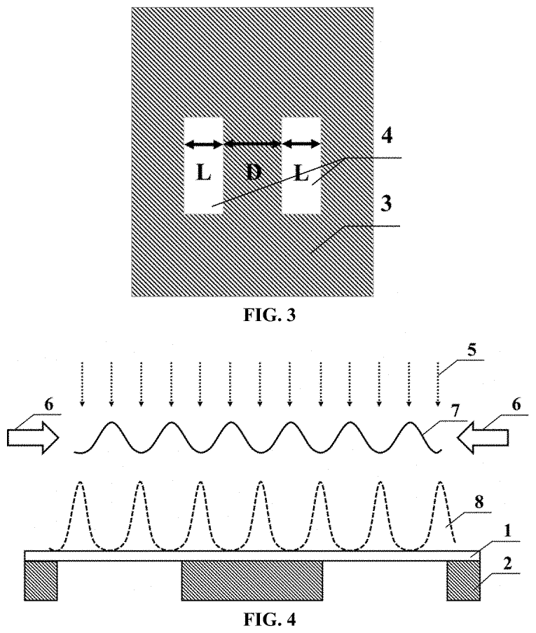

The mask substrate is manufactured to the mask. Based on the laser-focused atomic deposition technique, atoms are deposited to manufacture a self-traceability grating structure on the mask substrate designed and machined above. The self-traceability grating structure is used as the mask for subsequent interference lithography. The principle of the laser-focused atomic deposition technique is as shown in FIG. 4. A near-resonant laser standing wave field 7 formed by two beams of laser 6 having the same parameters and opposite directions interacts with a highly collimated atomic beam 5, so that the spatial distribution of the atomic beam 5 manifests a periodic distribution. The period is equal to the periodicity of the energy distribution of the laser standing wave field. Then the atomic beam 5 is deposited on the mask substrate to form a mask grating structure 8, i.e., the mask of interference lithography. Exemplarily, the atomic beam 5 may be emitted from a chromium atom furnace. When the atomic beam 5 passes through the laser standing wave field 7, the atoms are focused in an optical potential well toward an antinode due to the action of the dipole force, thus forming a periodic mask grating structure 8 on the mask substrate. The theoretical pitch value of the chromium atomic lithography grating is P₀=212.8 nm.

The period of the manufactured grating structure 8 is equal to half of the wavelength value of the laser 6. Meanwhile, in the experiment, the laser frequency is locked on the atomic transition energy level through the laser-induced fluorescence frequency stabilization technology. The atomic transition energy level depends on the type and structure of an atom, has nothing to do with external environmental conditions, and is an accurately known natural constant. Therefore, the period of the grating structure is traceable to the known natural constant of atomic transition frequency, and the grating is thus referred to as a self-traceability reference material.

The pitch value of the reference material is traceable and has high precision. Meanwhile, the reference material, as the mask, is to satisfy the optical properties for x-rays. The diffraction efficiency for x-rays is the most important and is closely related to a grating material and grating structural features (height, width and bottom layer). In addition, the bottom layer of a metal grating of the mask strongly absorbs x-rays, so it is also necessary to consider reducing the absorption of x-rays by the bottom layer when the metal grating of the reference material is selected.

Optionally, by way of example, a self-traceability metal (Cr) grating (pitch being 212.8 nm) is used as a mask and a 13.4 nm soft x-ray is used as an exposure light source for illustration, but the protection scope of the embodiments of the present application is not limited thereto.

To reduce the impact brought about by absorption of x-rays by the bottom layer, the experimental conditions for manufacturing the mask grating are as follows: the transverse dimension of a pre-collimating slit is (0.5 mm×2 mm), the power of the laser standing wave field is 50 MW, the beam waist diameter of a spot is 200 μm, the laser cooling power is 25 MW, and the spot dimension is (2 mm×24 mm). At this time, that ratio of the thickness B of the bottom layer to the peak-valley height value H of the grating reaches the optimal value which is about 1.

In the case where B/H=1, the peak-valley height value H and the full width at half maximum (FWHM) of the grating satisfy the following: the peak-valley height value H of the grating is in the range of 10 nm to 150 nm, an optimal height value H is 30 nm or 65 nm, the optimal height value H has the maximum diffraction efficiency for x-rays having a wavelength of 13.4 nm, when the optimal height value H is 30 nm, it corresponds to the scheme of the first-order interference lithography in the third step, and when the optimal height value H is 65 nm, it corresponds to the scheme of the second-order interference lithography in the third step; The FWHM of the grating is in the range of 30 nm to 180 nm, an optimal width value is 106 nm or 140 nm, the FWHM of the grating has the maximum diffraction efficiency for x-rays having a wavelength of 13.4 nm, when the FWHM of the grating is 106 nm, it corresponds to the scheme of the first-order interference lithography in the third step, and when the FWHM is 140 nm, it corresponds to the scheme of the second-order interference lithography in the third step.

In the third step, exposure is performed through soft x-ray interference lithography.

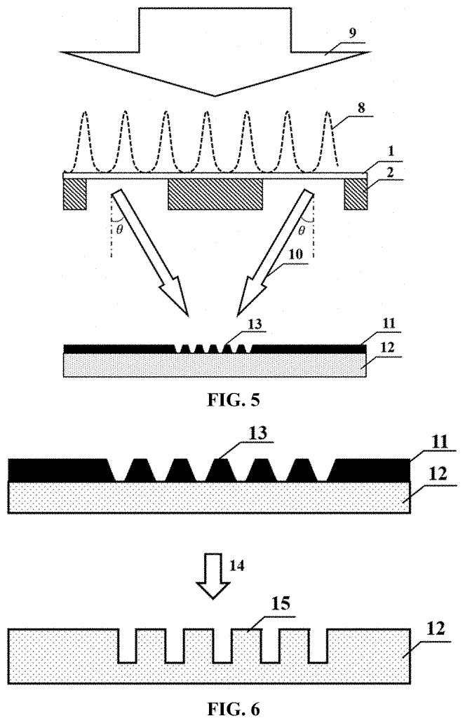

Taking the self-traceability grating reference materials as the mask, referring to FIG. 5, a photoresist 11 is exposed by a soft x-ray light 9 and subsequently developed to obtain a photoresist grating structure 13. Then, reactive ion beam etching is used to etch the pattern of the obtained photoresist structure 13 onto a substrate (a second substrate 12 shown in FIG. 5) under the photoresist to obtain grating reference materials having a small pitch. FIG. 5 shows a schematic diagram of soft x-ray interference lithography. The coherent x-ray light 9 from top to bottom is diffracted to diffraction light 10 by a mask (also referred to as a self-traceability grating reference material). The diffraction light 10 passes through a left window region and a right window region respectively and interferes at a certain spatial position behind the mask to form an interference fringe. The interference fringe exposes the photoresist 11. The photoresist grating structure 13 is obtained after the development process.

The incident light of the coherent x-ray light 9 is near-parallel light, the divergence angle is less than 1 mrad, the wavelength range is 1 nm to 20 nm, and the pitch value of the mask is greater than three times the wavelength of a light source. The photoresist 11 used is PMMA, HSQ, ZEP or other photoresists having a higher sensitivity. Generally, the PMMA photoresist is selected, and the PMMA photoresist may be coated on the second substrate 12 by spin coating. The second substrate 12 may be made of Si₃N₄, Si, Cr, Mo, or the like, and a Si material is generally selected.

The development process includes: developing the sample by using developer MIBK:IPA=1:3 for 45 s, cleaning the sample by using 95% ethanol for 30 s, and then slowly blowing dry the surface of the sample with nitrogen.

Before the reactive ion beam etching, the sample needs to be baked at 70° C. for 30 s to remove water vapor from the surface of the sample and ensure the etching quality. As shown in FIG. 6, the photoresist grating structure 13 is transferred onto the second substrate 12 by using a reactive ion beam etching process 14 to thus obtain grating reference materials 15 having a small pitch. Optionally, the second substrate 12 is a silicon substrate. The gas used to etch the silicon substrate is SF₆ and C₄H₈, the etching radio frequency (RF) power is 13 W, the inductive coupled plasma (ICP) power is 400 W, and the etching time is 25 s to 40 s. Then the photoresist on the surface of the silicon substrate is removed by using O₂, and the etching time is 120 s.

In this step of interference lithography,

$${P}_{1} = \frac{{P}_{0}}{2 N}$$

is derived from the grating diffraction equation P₀ sin θ=Nλ and the period of the fringe formed by interference of two beams of diffraction light 10. P₀ is the pitch value of the mask grating, P₁ is the pitch value of the exposure photoresist grating, N is the order of the diffraction light of the grating, and 9 is the diffraction angle of the grating. Optionally, N is taken to be 1 or 2 due to the limitation of grating diffraction efficiency. According to the diffraction order, the schemes for manufacturing a reference material by using interference lithography are divided into a scheme of first-order interference lithography (N=1) and a scheme of second-order interference lithography (N=2).

For the scheme of first-order interference lithography, the selected geometric dimensions of the mask substrate must satisfy D≥0.2L to ensure the quality of the exposure grating structure and balancing the interference of a high-order diffraction light on an exposure region. At the same time, considering the coherence of the soft x-ray light, D+2L≤L_{C} must be satisfied. L_{C} donates the coherence length of the soft x-ray (at the position of the mask grating). For the selection of the mask grating structure, the optimal peak-valley height value H of the grating is 30 nm, and the optimal FWHM of the grating is 106 nm. The thickness of the PMMA photoresist is from 60 nm to 80 nm, so as to ensure that the ratio of height to width of the photoresist structure does not exceed 2.

For the scheme of second-order interference lithography, the selected geometric dimensions of the mask substrate must satisfy D≥3L to ensure that the exposure region is not interfered by first-order and higher-order diffraction light. At the same time, considering the coherence of the x-ray light, D+2L≤L_{C} must be satisfied. L_{C} donates the coherence length of the soft x-ray (at the position of the mask grating). In addition, to ensure the consistency of grating height, the window width L satisfies that L≤300 μm. For the selection of the mask grating structure, the optimal peak-valley height value H of the grating is 65 nm, the optimal FWHM of the grating is 140 nm, and the FWHM needs to have good consistency. The thickness of PMMA photoresist is from 30 nm to 50 nm, so as to ensure that the ratio of height to width of the photoresist structure does not exceed 2.

According to the above two schemes, grating reference materials having a pitch value of 106.4 nm (first-order interference) and grating reference materials having a pitch value of 53.2 nm (second-order interference) can be obtained respectively.

According to this embodiment, the reference material at the scale of 100 nm or less can be manufactured. The pitch value of the reference material is accurately equal to ½N of the pitch value of the self-traceability reference material, and N is a diffraction order (N=1 or 2). The grating structure of the reference material manufactured by the method has the advantages of homogeneity in a large area, having pitch values at the scale of 10 to 100 nanometers, high precision, traceability, et al.

### Embodiment 3

As the feature dimensions of integrated circuits come to be less than 22 nm in technologies, it is more and more difficult for the traditional lithography to satisfy the production requirements of the key dimensions of lithography. In the semiconductor industry, extreme ultraviolet lithography (EUVL) has been recognized by the Semiconductor Equipment and Materials International (SEMI) as the most promising next generation lithography. A photoresist is a key material of the EUV lithography. The resolution, exposure sensitivity and line width roughness (LWR) of an extreme ultraviolet photoresist will directly affect the quality of etched patterns, thus affecting the yield of devices.

A photoresist refers to an etching-resistant thin film material whose solubility changes through illumination or radiation of ultraviolet light, electron beams, ion beams, x-rays and the like. The pattern on a mask can be transferred to a substrate through a series of steps (e.g. exposure, development and etching). To accurately transfer the pattern, the following performance indexes of the photoresist need to be paid attention to: (1) resolution, i.e., the minimum key dimension that the photoresist can reach under specific equipment and process conditions; (2) exposure sensitivity, i.e., the minimum energy required for the photoresist to change a dissolution rate when irradiated by light; (3) line edge roughness (LER) or line width roughness, line width roughness referring to the deviation of a photoresist line width from a target value due to edge roughness and line edge roughness referring to a roughness degree of the edge of a photoresist pattern.

According to the International Technology Roadmap for Semiconductors of the semiconductor industry, the following standards need to be met to achieve the mass production of EUV photoresists: (1) high resolution and a line width of 22 nm or less; (2) high exposure sensitivity being 10 mJ/cm²; (3) low line width roughness being 1.5 nm (3σ, where σ donates the standard deviation of a line edge point from a straight line). The above three performance parameters of the photoresist are not independent, and have a balance and restriction relationship. Factor Z may be used to denote correlation between the three parameters, and Z=(Sensitivity)×(LER)²×(Half pitch)³. Therefore, the balance between resolution, exposure sensitivity and line width roughness has become the biggest challenge to improve the performance of the EUV photoresist. Accurate measurement of parameters of the EUV photoresist provides the basis for the above research activities.

At present, high-resolution scanning electron microscopes (SEMs) or atomic force microscopes (AFMs) are widely used to measure and characterize the parameters of the EUV photoresist. However, two key problems in this method described below have not been solved. (1) The measurement stability, comparability and consistency of measuring instruments are not good. That is, for different instruments, even the same instrument, the results obtained from repeated measurements are different. The reason is that the length benchmark of a scanning image is not accurate due to different magnifications of the instruments and nonlinearity of the scanning tube of an atomic force microscope, thus bringing deviation to the measurement results of the exposure grating and making it difficult to accurately evaluate and compare the photoresist performance (2) The machining homogeneity and consistency of a soft x-ray interference lithography mask grating are not good, resulting in the difficulty in measuring and characterizing control variables. A general mask machining grating is obtained by using electron beam direct writing or laser interference lithography, and does not have self-traceability (i.e., a feature that structural parameters of the grating itself can be directly traceable to some natural benchmarks). Therefore, for the soft x-ray interference lithography, if a non-self-traceability grating is used, the experimental results obtained may be different due to the non-homogeneity of the non-self-traceability grating, resulting in the inability to make a comprehensive quantitative analysis of control variables on the performance of the extreme ultraviolet photoresist. The inaccuracy of photoresist performance evaluation limits the further innovation and development of the photoresist.

At present, many challenges still exist in the quality detection of the extreme ultraviolet photoresist in China, including a long test period, high cost, large uncertainty, difficulty in wide application and other problems. Although nanometer metrological reference gratings having periods of 100 nm and less have been developed at home and abroad, the above problem cannot be solved. This limits the development of high-end nanomanufacturing industries, especially the semiconductor industry.

Therefore, an extreme ultraviolet photoresist quality detection apparatus and method based on a self-traceability grating are provided in this embodiment of the present application.

The extreme ultraviolet photoresist quality detection apparatus based on a self-traceability grating is used for quality detection of the ultraviolet photoresist, and includes a synchrotron radiation x-ray interference lithography apparatus whose mask grating is manufactured based on atomic lithography.

Optionally, the synchrotron radiation x-ray interference lithography apparatus includes an extreme ultraviolet light source, an incident slit member, a first cylindrical lens, a second cylindrical lens, an exit slit member, a shutter, an XIL vacuum chamber and a charge-coupled device, where a photodiode and the mask grating are disposed in the XIL vacuum chamber. The light emitted from the extreme ultraviolet light source sequentially passes through the incident slit of the incident slit member, deflected by the first cylindrical lens and the second cylindrical lens, and passes through the exit slit of the exit slit member, the shutter, the photodiode and the mask grating to reach the charge-coupled device.

Optionally, the incident slit member is a water-cooling ultra-high-precision slit member.

Optionally, the surface of the first cylindrical lens is plated with gold.

The extreme ultraviolet photoresist quality detection method based on a self-traceability grating is used for quality detection of the extreme ultraviolet photoresist. The method includes a mask grating manufacturing step, a substrate (also referred to as a photoresist sample) acquisition step, a photoresist pattern acquisition step, and a quality detection step. In the mask grating manufacturing step, a mask grating is manufactured by using atomic lithography (also referred to as laser-focused atomic deposition technique). In the substrate (also referred to as a photoresist sample) acquisition step, a substrate (also referred to as a second substrate) coated with an extreme ultraviolet photoresist film is acquired. In the photoresist pattern acquisition step, double grating interference is performed on the substrate based on the acquired mask grating to obtain a pattern of a photoresist to be detected which is a pattern of an extreme ultraviolet photoresist. In the quality detection step, the theoretical pitch value of the pattern of the photoresist to be detected is calculated according to the characteristic of the self-traceability and based on the pitch value of the mask grating, and the quality of the extreme ultraviolet photoresist to be detected is determined by taking the theoretical pitch value of the pattern of the photoresist to be detected as a scale.

Optionally, an atom used in the atomic lithography includes a chromium atom, an aluminum atom or an iron atom.

Optionally, the substrate is a silicon wafer.

Optionally, the pitch value of the detected photoresist pattern is calculated by a following expression:

$$P = \frac{{P}_{0}}{2 N} .$$

P denotes the pitch value of the pattern of the photoresist to be detected, P₀ denotes the pitch value of the mask grating, and N is a diffraction order of the double grating interference.

Optionally, the diffraction order of the double grating interference is a first order or a second order.

Optionally, in the photoresist pattern acquisition step, double grating interference is performed by using the above-mentioned extreme ultraviolet photoresist quality detection apparatus based on a self-traceability grating.

Compared with the related art, this embodiment of the present application has advantages described below.

(1) According to the extreme ultraviolet photoresist quality detection apparatus provided in this embodiment of the present application, the mask grating is manufactured by the atomic lithography. The pitch value of the mask grating has the self-traceability and can provide a direct and accurate scale for measurement data of the EUV photoresist, solving the experimental error problem caused by measurement equipment, and improving the precision of EUV photoresist quality detection.

(2) The water-cooling ultra-high-precision slit member is selected as the incident slit member of the extreme ultraviolet photoresist quality detection apparatus provided in this embodiment of the present application to reduce the thermal load on the deflection lens. The exit slit ensures the spatial coherence of the beam. The surface of the first cylindrical lens is plated with gold so as to be used for adjusting a deflection angle, reducing the downstream thermal load, and also implementing the function of high frequency filtering. The second cylindrical lens has the functions of removing higher harmonics, adjusting deflection and performing focusing and collimation. The extreme ultraviolet photoresist quality detection apparatus has high detection precision and is stable and reliable.

(3) According to the extreme ultraviolet photoresist quality detection method based on a self-traceability grating provided in this embodiment of the present application, the mask grating is manufactured by using the atomic lithography and thus has the characteristic of self-traceability. After double grating interference, the pitch value of the acquired photoresist pattern to be detected keeps the same self-traceability as the mask grating, thus making the measurement result more accurate.

### Embodiment 4

The extreme ultraviolet photoresist quality detection apparatus based on a self-traceability grating provided in this embodiment is used for quality detection of an ultraviolet photoresist, and includes a synchrotron radiation x-ray interference lithography apparatus whose mask grating 108 is manufactured based on atomic lithography.

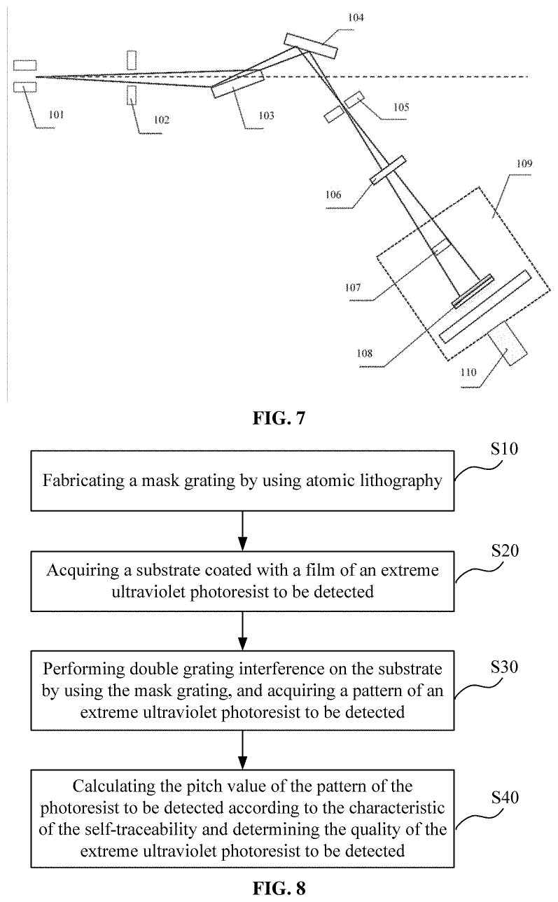

Optionally, as shown in FIG. 7, the synchrotron radiation x-ray interference lithography apparatus includes an extreme ultraviolet light source 101, an incident slit member 102, a first cylindrical lens 103, a second cylindrical lens 104, an exit slit member 105, a shutter 106, an XIL vacuum chamber 109 and a charge-coupled device 110. A photodiode 107 and the mask grating 108 are disposed in the XIL vacuum chamber 109.

The light emitted from the extreme ultraviolet light source 101 passes through the incident slit of the incident slit member 102 and is deflected by the first cylindrical lens 103 as well as the second cylindrical lens 104, and then continues passing through the exit slit of the exit slit member 105, the shutter 106, the photodiode 107, the mask grating 108 and finally reach the charge-coupled device 110.

The incident slit member 102 is a water-cooling ultra-high-precision slit member. The surface of the first cylindrical lens 103 is plated with gold.

As shown in FIG. 8, an extreme ultraviolet photoresist quality detection method based on a self-traceability grating is further provided in this embodiment, is used for quality detection of an ultraviolet photoresist, and includes steps S10 to S40.

In mask grating manufacturing step S10, a mask grating is fabricated by using atomic lithography. An atom used in the atomic lithography is a chromium atom, an aluminum atom or an iron atom.

In substrate acquisition step S20, a substrate coated with a film of an extreme ultraviolet photoresist to be detected is acquired. Optionally, the substrate is a silicon wafer.

In photoresist pattern acquisition step S30, double grating interference is performed based on the acquired mask grating, substrate and the above-mentioned extreme ultraviolet photoresist quality detection apparatus assembling with a self-traceability grating so that a pattern of an extreme ultraviolet photoresist to be detected is acquired. The diffraction order of the double grating interference is a first order or a second order.

The extreme ultraviolet photoresist is subjected to the double grating interference to thus obtain a pattern of the extreme ultraviolet photoresist to be detected, and then a photoresist grating structure is obtained from the pattern of the extreme ultraviolet photoresist to be detected through a development process.

In quality detection step S40, the theoretical pitch value of the pattern of the photoresist to be detected is calculated according to the characteristic of the self-traceability and based on the pitch value of the mask grating, and the quality of the extreme ultraviolet photoresist to be detected is detected by taking the theoretical pitch value of the pattern of the photoresist to be detected as a scale.

Optionally, the pattern of the photoresist to be detected and the photoresist grating structure have the same theoretical pitch value. The theoretical pitch value of the photoresist grating structure can also be calculated based on the pitch value of the mask grating structure of the mask, and the quality of the extreme ultraviolet photoresist to be detected is detected by taking the theoretical pitch value of the photoresist grating structure as a scale.

The pitch value of the pattern of the extreme ultraviolet photoresist to be detected is calculated by a following expression:

$$P = \frac{{P}_{0}}{2 N} .$$

P denotes the pitch value of the pattern of the extreme ultraviolet photoresist to be detected, P₀ denotes the pitch value of the mask grating structure in the mask, and N is a diffraction order of the double grating interference.

### Specific Implementation

In the extreme ultraviolet photoresist quality detection method based on a self-traceability grating, chromium atomic lithography is used for manufacturing the mask grating and x-ray interference lithography is used to obtain positive and negative first-order frequency doubling SEM images. The specific implementation process includes sample manufacturing and measurement and calculation.

1. Sample Manufacturing

In step one, a mask grating is manufactured by using the chromium atomic lithography. The atomic lithography mainly uses the dipole force of a laser standing wave field to operate the movement of the atom, so that a periodic grating structure is formed on the substrate after a cooled atomic beam passes through the laser standing wave field. According to the electromagnetic theory, the dipole force is generated as described below. Atoms are induced by an alternating electric field in a light field to generate an oscillating electric dipole moment. The electric dipole moment interacts with the electric field to generate a force proportional to the field strength gradient.

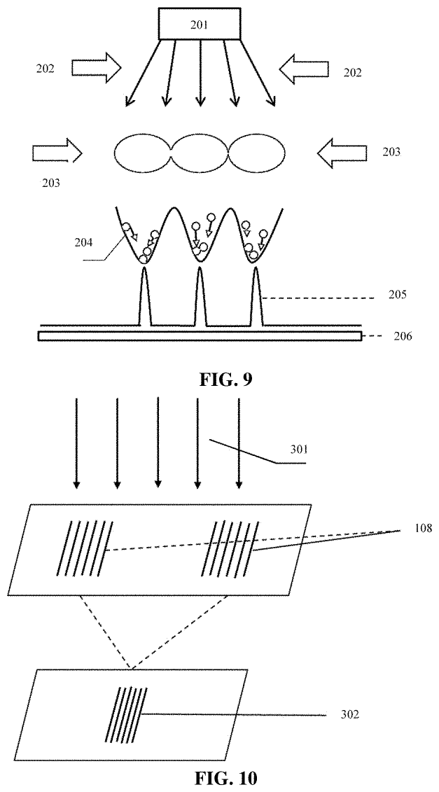

FIG. 9 shows a principle diagram of a mask grating manufactured by using the chromium atomic lithography. 201 indicates a chromium atom furnace. The atoms emitted from the atom furnace pass through the cooling laser beam 202 and then pass through the standing wave field 203. The atoms are focused in an optical potential well 204 toward an antinode due to the action of the dipole force, thus forming a periodic grating structure 205 on the substrate 206. The theoretical periodic pitch value of the chromium atomic lithography grating is P₀=212.8 nm.

In step two, a substrate coated with an EUV photoresist film is provided, where the substrate is a silicon wafer.

In step three, double grating interference is performed on the substrate by a synchrotron radiation x-ray interference lithography apparatus to obtain a one-dimensional line pattern to be detected. For the synchrotron radiation x-ray interference lithography apparatus, reference may be made to FIG. 7. In FIG. 7, 101 denotes an extreme ultraviolet light source. The light emitted from the extreme ultraviolet light source passes through the incident slit of an incident slit member 102 and deflected by a first cylindrical lens 103 and a second cylindrical lens 104 to reach the exit slit of the exit slit member 105. The incident slit defines the receiving angle of an entire beam line so that requirements for the dimension of a spot and the homogeneity of light intensity distribution on the mask are satisfied. A water-cooling ultra-high-precision slit is selected to reduce the thermal load on the deflection lens. The exit slit defines the size of a secondary light source to ensure the spatial coherence of the light beam. Of the two cylindrical deflection lenses used, the surface of the first cylindrical lens 103 is plated with gold so as to be used for adjusting a deflection angle, reducing the downstream thermal load, and also implementing the function of high frequency filtering. The second cylindrical lens 104 has the functions of removing higher harmonics, adjusting deflection and performing focusing and collimation. The light passing through the exit slit then passes through a shutter 106 to an XIL vacuum chamber 109. The XIL vacuum chamber 109 includes a photodiode 107 and a mask grating 108. The mask grating manufactured by using atomic lithography is used. The digit 110 denotes CCD (CCD refers to a charge-coupled device and is a detection element that uses the amount of charge to indicate the magnitude of a signal and that transmits the signal in a coupling manner).

FIG. 10 is a schematic diagram of a one-dimensional EUV photoresist line pattern obtained based on double grating interference lithography. An extreme ultraviolet light beam 301 is subjected to double grating interference 108 to obtain a one-dimensional EUV photoresist line pattern (i.e., a pattern of a photoresist to be detected 302). In this embodiment, positive and negative first-order diffraction light (N=1) is used for interference lithography, and the pitch value of the manufactured sample is half of the pitch value of the mask grating, i.e.,

$$P = \frac{{P}_{0}}{2 N} = 106.4 nm .$$

2. Measurement and Calculation

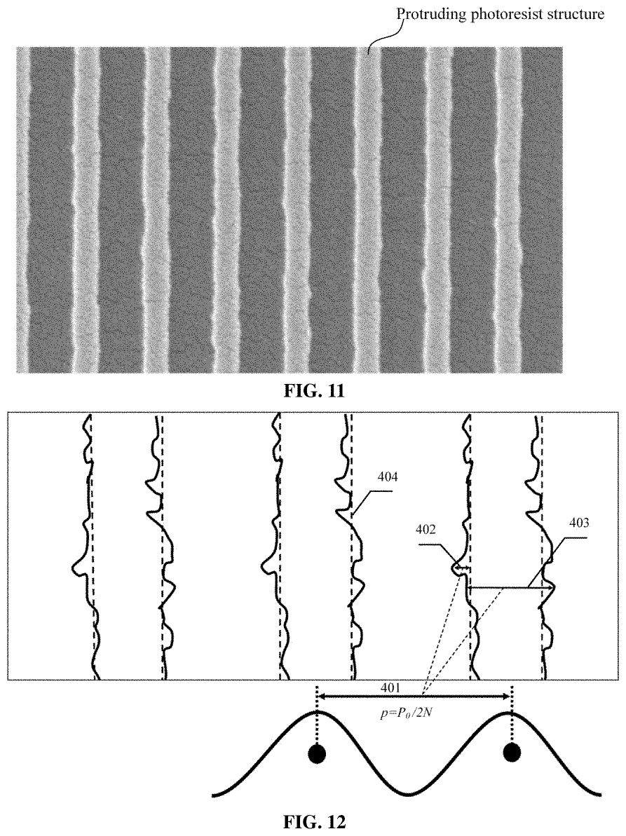

In step four, the EUV photoresist to be detected is characterized by imaging equipment such as a scanning electron microscope or an atomic force microscope. The scanning electron microscope is used in this embodiment. FIG. 11 is an image of an exposure sample (i.e., the EUV photoresist to be detected) produced by a scanning electron microscope. From the image produced by the scanning electron microscope in FIG. 11, the image includes a plurality of protruding photoresist structures, and each protruding photoresist structure has a certain width. FIG. 11 exemplarily shows one protruding photoresist structure.

In step five, a new scale is established for the image to be measured. Based on the analysis of the center of gravity method or zero-crossing method of the image to be measured, the line segment between centers of gravity of a certain group of adjacent profiles on a reasonable profile curve is acquired as the new scale of the image. The length of the line segment is set to

$$P = \frac{{P}_{0}}{2 N} = 106.4 nm ,$$

and the parameters to be measured are subsequently determined based on the pixel point equal proportion analysis method.

FIG. 12 shows a schematic diagram of line edge roughness and line width roughness measured by using a pitch value of a self-traceability grating as a scale. 401 denotes the pitch value of the exposure sample obtained by using x-ray interference lithography (i.e., the pitch value of the pattern of the photoresist to be detected). 404 denotes an ideal line edge. 402 and 403 denote a line edge deviation value at some point and a line edge line width value at some point, respectively. Since the pitch value of the exposure sample keeps the same self-traceability as the mask grating subjected to atomic lithography, the measurement result is more accurate.

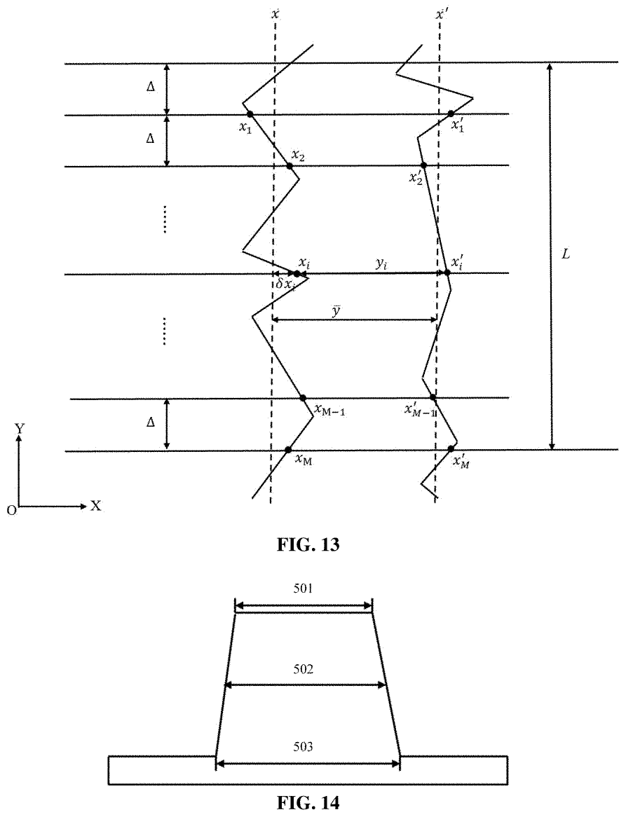

FIG. 13 is a schematic diagram of a boundary position deviation value and a line width deviation value according to an embodiment of the present application. FIG. 13 shows a boundary position deviation value and a line width deviation value of a protruding photoresist structure of FIG. 11. The LER can be calculated and obtained according to the boundary position deviation value, and the LWR can be calculated and obtained according to the line width deviation value. Referring to FIG. 13, a measurement window having a length of L is selected, and the edges of the photoresist structures within this window are equally spaced by M profile lines, and the interval between two adjacent profile lines is Δ, so L=M·Δ. In FIG. 13, in the x-axis direction, xᵢ (i=1, 2, . . . M) denotes the left boundary position of an i-th profile line, and xᵢ′ (i=1, 2, . . . M) denotes the right boundary position of the i-th profile line. The average left boundary position of the i-th profile line is determined as:

$$\overline{x} = \frac{{\sum }_{i = 1}^{M} {x}_{i}}{M} .$$

The average right boundary position of the i-th profile line is determined as:

$${\overline{x}}^{′} = \frac{{\sum }_{i = 1}^{M} {x}_{i}^{′}}{M} .$$

The deviation between the left boundary position and the left average boundary position of the i-th profile line is: δxᵢ=xᵢ−x̅, and the deviation between the right boundary position and the right average boundary position is: δxᵢ′=xᵢ′−x̅′. The measured standard error of the left boundary of the i-th profile line, i.e., the left LER (expressed as ζ_{LER-1}), can be calculated as follows:

$${ζ}_{L E R - 1} = \sqrt{\frac{1}{M - 1} {\sum }_{i = 1}^{M} {( δ {x}_{i} )}^{2}} = \sqrt{\frac{1}{M - 1} {\sum }_{i = 1}^{M} {( {x}_{i} - \overline{x} )}^{2}} .$$

Similarly, the measured standard error of the right boundary of the i-th profile line, i.e., the right LER (expressed as ζ_{LER-2}), can be calculated as follows:

$${ζ}_{L E R - 2} = \sqrt{\frac{1}{M - 1} {\sum }_{i = 1}^{M} {( δ {x}_{i}^{′} )}^{2}} = \sqrt{\frac{1}{M - 1} {\sum }_{i = 1}^{M} {( {x}_{i}^{′} - {\overline{x}}_{i}^{′} )}^{2}} .$$

The left LER and right LER determined on other profile lines are calculated by using the same calculation method and process as described above, and will not be repeated here.

In addition, in FIG. 13, yᵢ (i=1, 2, . . . M) denotes the true line width value determined by the i-th profile line. y̅ denotes the value of the average line width between the left average boundary position and the right average boundary position of the i-th profile line. The deviation between the true line width value determined by the i-th profile line and the average line width value is δyᵢ=yᵢ−y̅. According to the definition of LWR given by the International Technology Roadmap for Semiconductors (ITRS), the LWR is defined as three times the standard deviation of the local line width variation, i.e.,

$${ζ}_{LWR} = 3 \sqrt{\frac{1}{M - 1} {\sum }_{i = 1}^{M} {( δ {y}_{i} )}^{2}} = 3 \sqrt{\frac{1}{M - 1} {\sum }_{i = 1}^{M} {( {y}_{i} - \overline{y} )}^{2}} .$$

In step six, the following three measurement values of a one-dimensional line pattern is obtained: (1) line width resolution; (2) line edge roughness; (3) line width roughness. The line width resolution of the photoresist is determined by the minimum key dimension of the exposure sample.

FIG. 14 is a schematic diagram of key dimensions according to an embodiment of the present application. 501 denotes a top dimension, 502 denotes a middle dimension, and 503 denotes a bottom dimension. According to the relevant regulations of international comparison, the width corresponding to the half-height position of a line is usually taken as the width value of the line. Ten successive groups of FWHM values (σ₁, σ₂, σ₃, . . . , σ₉, σ₁₀) of the grating measured and obtained in any region of the exposure sample are averaged, i.e., σ̅, and then

$$\overline{σ} = \frac{1}{10} {\sum }_{i = 1}^{10} {σ}_{i} .$$

The average value σ̅ can be regarded as the key dimension of the sample, reflecting the line width resolution of the photoresist.

The optional embodiments of the present application are described above in detail. It is to be understood that those skilled in the art can make many modifications and changes according to the concept of the present application without creative work. Therefore, all solutions that can be obtained by those skilled in the art through logical analysis, reasoning or limited experiments on the basis of the related art according to the concept of the present application shall fall within the scope determined by the claims.

What is claimed is:

1. A method for manufacturing grating reference materials having a self-traceability, based on laser-focused atomic deposition technique and soft x-ray interference lithography, comprising:
acquiring a mask substrate, wherein the mask substrate comprises a window region and a non-window region, the window region comprises a first substrate, and the non-window region comprises a film and the first substrate;
fabricating a self-traceability mask on the mask substrate by using the laser-focused atomic deposition technique;
acquiring a photoresist sample which comprises an extreme ultraviolet photoresist and a second substrate; exposing the extreme ultraviolet photoresist by combining the self-traceability mask with the soft x-ray interference lithography, and then performing a development process after exposing to obtain a photoresist grating structure; and
transferring the photoresist grating structure to the second substrate to obtain the grating reference materials, wherein the grating reference materials have characteristics of the self-traceability and small pitch value;
wherein a pitch value of a mask grating structure of the self-traceability mask is 2N times a theoretical pitch value of the grating reference materials, and N is a positive integer greater than or equal to 1.

2. The method of claim 1, wherein N is an diffraction order of grating in double grating interference, and N used is a first order or a second order;
in a case where N is the first order, N=1; and
in a case where N is the second order, N=2.

3. The method of claim 2, wherein the theoretical pitch value of the grating reference materials is calculated by a following expression:
$$P = \frac{{P}_{0}}{2 N} ,$$
wherein P denotes the theoretical pitch value of the grating reference materials, and P₀ denotes the pitch value of the mask grating structure.

4. The method of claim 3, wherein a theoretical pitch value of the photoresist grating structure is the same as the theoretical pitch value of the grating reference materials.

5. The method of claim 2, wherein the window region is x-ray transparent, the non-window region is x-ray opaque, a number of window regions is two, and the two window regions have a same size and are symmetrically distributed.

6. The method of claim 5, wherein a soft x-ray used in the soft x-ray interference lithography has coherence;
in the case where N is the first order, the two window regions satisfy:
D≥0.2L, and D+2L≤L_{C}; or
in the case where Nis the second order, the two window regions satisfy:
D≥3L, and D+2L≤L_{C}, L≤300 μm;
wherein D denotes a width of a non-window region between the two window regions, L denotes a width of each of the two window regions, and L_{C} denotes a coherence length of the soft x-ray passing through the self-traceability mask.

7. The method of claim 2, wherein
in the case where N is the first order, a peak-valley height value H of the photoresist grating structure and a full width at half maximum (FWHM) of the photoresist grating structure respectively satisfy:
$$5 \% \leq \frac{H}{{P}_{0}} \leq 50 \% and$$
$$15 \% \leq \frac{FWHM}{{P}_{0}} \leq 85 \% ;$$
or
in the case where N is the second order, a peak-valley height value H of the photoresist grating structure and an FWHM of the photoresist grating structure respectively satisfy:
$$5 \% \leq \frac{H}{{P}_{0}} \leq 70 \% and$$
$$20 \% \leq \frac{FWHM}{{P}_{0}} \leq 80 \% ;$$
wherein P₀ denotes the pitch value of the mask grating structure of the self-traceability mask.

8. The method of claim 1, wherein a thickness h of the film of the mask substrate satisfies: 50 nm≤h≤300 nm, a surface roughness of the film is less than 0.3 nm, and a maximum height value of a surface profile of the film is less than 2 nm.

9. The method of claim 1, wherein an atom used in the laser-focused atomic deposition technique is a chromium atom, an aluminum atom or an iron atom.

10. The method of claim 1, wherein a divergence angle of an extreme ultraviolet light source used in the soft x-ray interference lithography is less than 1 mrad, and the pitch value of the mask grating structure of the self-traceability mask is greater than three times a wavelength of the extreme ultraviolet light source.

11. The method of claim 1, wherein transferring the photoresist grating structure to the second substrate comprises:
using a reactive ion beam etching process to transfer the photoresist grating structure to the second substrate.

12. The method of claim 1, wherein the extreme ultraviolet photoresist is made of poly-methyl methacrylate (PMMA), hydrogen silisesquipoxane (HSQ) or ZEP, and the second substrate is made of silicon, silicon nitride, aluminum or chromium.

13. The method of claim 1, wherein a theoretical pitch value of the photoresist grating structure has characteristics of the self-traceability and is configured as an accurate scale to determine a quality of the extreme ultraviolet photoresist.
